(19) United States
(12) Patent Application Publication
(10) Pub. No.: US 2019/0058066 A1
(43) Pub. Date: Feb. 21, 2019

(54) SYSTEM AND METHOD FOR PRINTING ELECTRODES OF SOLAR CELL BY AUTOMATICALLY POSITIONING

(71) Applicant: Beijing Juntai Innovation Technology Co., Ltd., Beijing (CN)

(72) Inventors: Zheng Guo, Beijing (CN); Cen Cai, Beijing (CN); Xudong Wang, Beijing (CN); Tongyang Huang, Beijing (CN); Huibin Fan, Beijing (CN)

(73) Assignee: Beijing Juntai Innovation Technology Co., Ltd., Beijing (CN)

(21) Appl. No.: 16/050,413

(22) Filed: Jul. 31, 2018

(30) Foreign Application Priority Data
Aug. 16, 2017 (CN) 201710702073.9

(51) Int. Cl. H01L 31/0224; H01L 31/18; H05K 3/12

(52) U.S. Cl. CPC H01L 31/022425; H05K 3/1216; H01L 31/18

(57) ABSTRACT

A system and method for printing electrodes of a solar cell by automatically positioning are provided. The system includes: a transparent glass plate configured to support a solar cell, an electrode printing apparatus arranged above the transparent glass plate and configured to form electrodes on the solar cell by screen printing, a visual positioning module arranged right below the transparent glass plate and configured to acquire position information of the solar cell, and a main control module configured to adjust a position of the electrode printing apparatus according to the position information sent by the visual positioning module.

### CROSS-REFERENCES TO RELATED APPLICATIONS

This application claims priority to Chinese patent application No. CN201710702073.9, filed on Aug. 16, 2017, the disclosure of which is incorporated herein by reference in its entirety.

### TECHNICAL FIELD

The present disclosure relates to a manufacturing device for solar cells, and for example, relates to a system and method for printing electrodes of a solar cell by automatically positioning.

### BACKGROUND

Photovoltaic power generation is a type of clean energy and is rapidly developed in recent years. With respect to a heterojunction solar cell, a screen printing device for making electrodes of the solar cell is an important process device. A visual positioning module in the screen printing device plays a significant role in electrode printing quality and precision.

In a relevant technology, the visual positioning module is arranged above a position for positioning the solar cell. After the solar cell is positioned, the solar cell is transferred to a printing position. A printing head regulates its own position according to a positioning result of the visual positioning module and then prints the electrodes on the solar cell.

However, in a process of conveying the solar cell to the printing position, due to influences of the own precision and the variation of the conveying implementation of the convey mechanism, the solar cell has a position error when arriving at the printing position. The printing head regulates its own position according to positioning information of the visual positioning module and prints the electrodes on the solar cell. Therefore, undesirable phenomena such as poor printing registration, cold solder joint and the like when connecting the solar cells in series by welding and further affecting manufacturing efficiency and manufacturing quality of the solar cell module.

### SUMMARY

The present disclosure provides a system and method for printing electrodes of a solar cell by automatically positioning, so as to solve problems in a relevant technology, enhance printing and positioning precision of the solar cell and further improve processing efficiency and processing quality of a solar cell module.

The present disclosure provides a system for printing electrodes of a solar cell by automatically positioning, and the system includes:
a transparent glass plate configured to support a solar cell;
an electrode printing apparatus arranged above the transparent glass plate and configured to form electrodes on the solar cell by screen printing;
a visual positioning module arranged right below the transparent glass plate and configured to acquire position information of the solar cell; and
a main control module configured to adjust a position of the electrode printing apparatus according to the position information sent by the visual positioning module.

In an exemplary embodiment, the transparent glass plate is provided with a vacuum chunk configured to absorb the solar cell.

In an exemplary embodiment, the system further includes a conveying mechanism configured to transmit the solar cell onto the transparent glass plate.

In an exemplary embodiment, the electrode printing apparatus includes a blade component, an ink return blade, a screen frame and a screen.

In an exemplary embodiment, the visual positioning module includes a charge coupled device camera.

In an exemplary embodiment, the system further includes a drying apparatus configured to dry the solar cell after the electrodes have been formed on the solar cell.

In an exemplary embodiment, the system further includes a light source arranged on the transparent glass plate.

The present disclosure also provides a method for printing electrodes of a solar cell by automatically positioning, and the method includes the following steps:

transmitting a solar cell onto a transparent glass plate;

acquiring position information of the solar cell;

adjusting a position of the electrode printing apparatus according to the position information of the solar cell; and

forming electrodes on the solar cell by screen printing.

In an exemplary embodiment, the step of transmitting a solar cell onto a transparent glass plate includes: transmitting the solar cell onto the transparent glass plate by means of a conveying mechanism and absorbing the solar cell onto the transparent glass plate by means of a vacuum chuck.

In the system and method for printing electrodes of a solar cell by automatically positioning provided in the present disclosure, the visual positioning module which is arranged right below the transparent glass plate is used to acquire the position information of the solar cell, and the position of the electrode printing apparatus is adjusted accordingly. Compared with a configuration in the relevant technology that a position for positioning and a position for printing are separated, the present disclosure enhances the positioning precision and further improves the production efficiency and the quality of the cell module.

### BRIEF DESCRIPTION OF DRAWINGS

FIG. 1 is a diagram illustrating an operation principle of a system for printing electrodes of a solar cell by automatically positioning provided by an embodiment;

FIG. 2 is a diagram illustrating a state of a system for printing electrodes of a solar cell by automatically positioning when conveying the solar cell provided by an embodiment;

FIG. 3 is a diagram illustrating a simplified control configuration of a system for printing electrodes of a solar cell by automatically positioning provided by an embodiment; and

FIG. 4 is a flow chart illustrating a method for printing electrodes of a solar cell by automatically positioning provided by an embodiment.

### LIST OF REFERENCE NUMERALS

1—transparent glass plate; 2—solar cell; 3—electrode printing apparatus; 31—blade component; 32—ink return blade; 33—screen frame; 34—screen; 4—visual positioning module; 5—main control module; 6—conveying mechanism; L—range of field of view; 11—vacuum chuck; 12—light source; 7—drying apparatus; and 41—CCD camera.

### DETAILED DESCRIPTION

Embodiments of the present disclosure are described in detail below. Examples of described embodiments are shown in drawings. Same or similar numerals represent same or similar elements or elements with same or similar functions throughout. Embodiments described below by referring to drawings are exemplary, are only used to explain the present disclosure and shall not be construed as a limitation to the present disclosure.

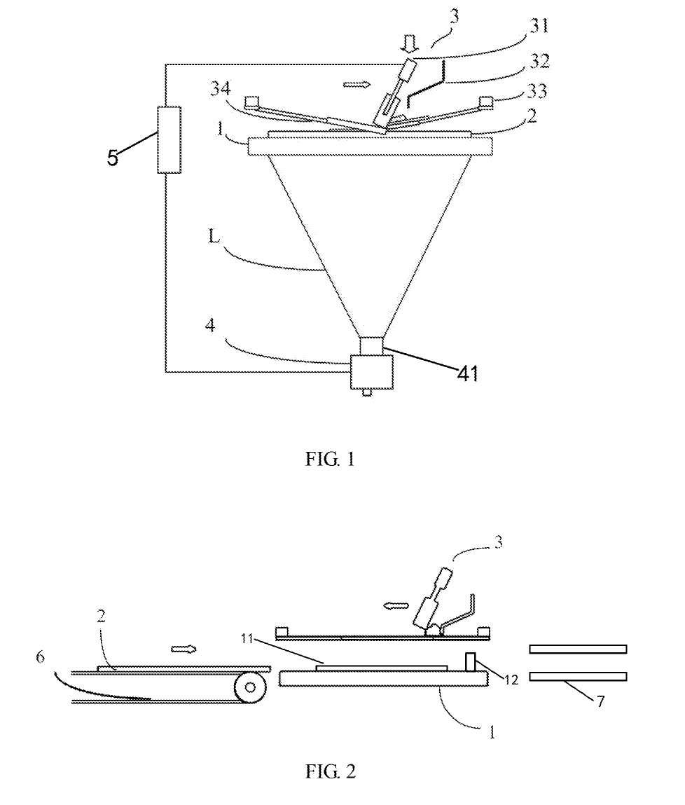

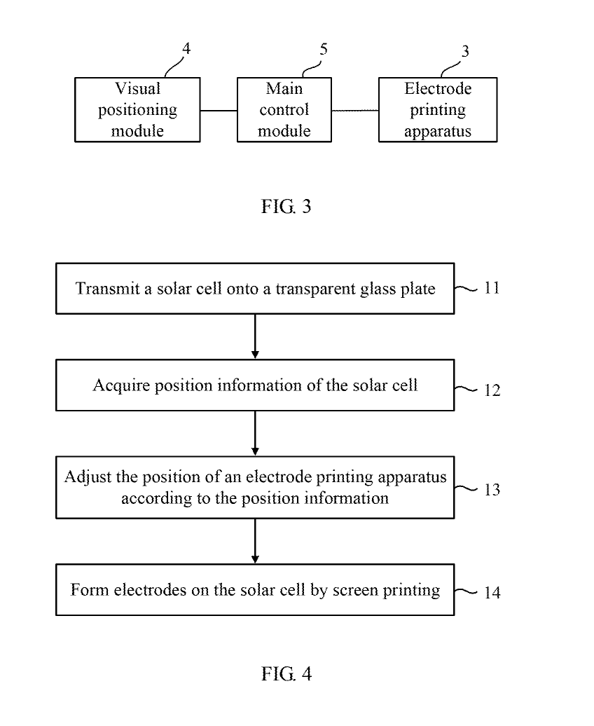

FIG. 1 is a diagram illustrating the operating principle of a system for printing electrodes of a solar cell by automatically positioning provided by an embodiment. FIG. 2 is a diagram illustrating a state of a system for printing electrodes of a solar cell by automatically positioning when conveying the solar cell provided by an embodiment. FIG. 3 is a diagram illustrating a simplified control configuration of a system for printing electrodes of a solar cell by automatically positioning. As shown in FIG. 1, FIG. 2 and FIG. 3, embodiments of the present disclosure provide a system for printing electrodes of a solar cell by automatically positioning. The system includes a transparent glass plate 1, an electrode printing apparatus 3, a visual positioning module 4 and a main control module 5.

The transparent glass plate 1 is configured to support a solar cell 2. The electrode printing apparatus 3 is arranged above the transparent glass plate 1 and configured to conduct electrode printing on the solar cell 2. The visual positioning module 4 is arranged directly below the transparent glass plate 1 and configured to obtain position information of the solar cell 2. The main control module 5 is configured to adjust a printing position of the electrode printing apparatus 3 according to the position information sent by the visual positioning module 4.

When a sensor detects that the solar cell 2 is positioned on the transparent glass plate 1, the visual positioning module 4 which is arranged directly below the transparent glass plate 1 detects the position of the solar cell 2, collects position information and then sends the position information to the main control module 5. The main control module 5 adjusts the printing position of the electrode printing apparatus 3 according to the position information. After the electrode printing apparatus 3 is regulated to a proper position, screen printing is conducted on the solar cell 2 for forming electrodes. After the screen printing is completed, the solar cell is transmitted out by the conveying mechanism 6.

In the system for printing electrodes of a solar cell by automatically positioning provided in embodiments of the present disclosure, the visual positioning module 4 which is arranged right below the transparent glass plate 1 is employed to obtain the position information of the solar cell 2, and the position of the electrode printing apparatus 3 is adjusted according to the position information. Compared with a configuration in the relevant technology that the position for positioning and the position for printing are separated, the present disclosure eliminates a process of transmitting the solar cell 2 from the position for positioning to the position for printing, thereby enhancing the positioning precision and further improving the production efficiency and the quality of the cell module.

In an embodiment, a vacuum chuck 11 is arranged on the transparent glass plate 1 and is configured to absorb the solar cell 2. The solar cell 2 is attached to the transparent glass plate 1 by vacuum suction of the vacuum chuck 11. When the solar cell 2 is positioned on the transparent glass plate 1, the solar cell 2 can be fixed more firmly through the vacuum chuck 11, thereby enhancing the positioning precision of the solar cell 2, preventing the solar cell 2 from shaking in a subsequent screen printing process and further improving the processing quality of the solar cell 2.

In an embodiment, a light source 12 is also arranged on the transparent glass plate 1 and is configured to provide a light source for the visual positioning module 4 so that the visual positioning module 4 works more accurately, thereby enhancing the positioning precision of the solar cell 2.

By referring to FIG. 2, the system may further include a conveying mechanism 6 configured to transmit the solar cell 2 onto the transparent glass plate 1. The conveying mechanism 6 may be implemented in various structures. In the present embodiment, the conveying mechanism 6 may include a conveyor belt and a roller. The solar cell 2 is transmitted onto the transparent glass plate 1 through cooperation of the conveyor belt and the roller. After the solar cell 2 arrives a position at where the screen printing is to be performed, the conveying mechanism 6 stops operating for the subsequent positioning, position information acquisition and screen printing.

It can be understood by those skilled in the art that the electrode printing apparatus 3 may include a blade component 31, an ink return blade 32, a screen frame 33 and a screen 34, as shown in FIG. 1.

The visual positioning module 4 may include a charge coupled device (CCD) camera 41. By referring to FIG. 1, the range of field of view L of the CCD camera 41 may completely cover the position of the solar cell 2, thereby ensuring accuracy of information collection.

After the electrodes are formed on the solar cell 2 by screen printing, the solar cell 2 may be transmitted out by the conveying mechanism 6. In an embodiment, the system may further include a drying apparatus 7 configured to dry the solar cell 2 on which the electrodes have been formed.

FIG. 4 is a flow chart illustrating a method for printing electrodes of a solar cell by automatically positioning provided by an embodiment. The present embodiment provides a method for printing electrodes of a solar cell by automatically positioning, and the method includes the following steps.

In step 11: the solar cell 2 is transmitted onto the transparent glass plate 1.

In the present embodiment, step 11 may include: transmitting the solar cell 2 onto the transparent glass plate 1 by means of the conveying mechanism 6, and absorbing the solar cell 2 to the transparent glass plate 1 by the vacuum chuck.

Step 12: position information of the solar cell 2 is collected.

Step 13: the position of the electrode printing apparatus 3 is adjusted according to the position information such that the electrode printing apparatus 3 is at a suitable position for performing screen printing.

Step 14: screen printing is conducted on the solar cell 2 to form electrodes.

In the method for printing electrodes of a solar cell by automatically positioning provided in embodiments of the present disclosure, the visual positioning module arranged right below the transparent glass plate is used to collect the position information of the solar cell, and the position of the electrode printing apparatus is adjusted accordingly. Compared with a configuration in the relevant technology that the position for positioning and the position for screen printing are separated, the present disclosure enhances the positioning precision and further improves the production efficiency and the quality of the cell module.

### INDUSTRIAL APPLICABILITY

The system and method for printing electrodes of a solar cell by automatically positioning provided in the present disclosure enhance the positioning precision and the production efficiency and the quality of the cell module.

What is claimed is:

1. A system for printing electrodes of a solar cell by automatically positioning, comprising:
a transparent glass plate configured to support the solar cell;
an electrode printing apparatus arranged above the transparent glass plate and configured to print electrodes on the solar cell;
a visual positioning module arranged right below the transparent glass plate and configured to acquire position information of the solar cell; and
a main control module configured to adjust a position of the electrode printing apparatus according to the position information sent by the visual positioning module.

2. The system for printing electrodes of a solar cell by automatically positioning according to claim 1, wherein the transparent glass plate is provided with a vacuum chunk configured to absorb the solar cell.

3. The system for printing electrodes of a solar cell by automatically positioning according to claim 1, further comprising: a conveying mechanism configured to transmit the solar cell onto the transparent glass plate.

4. The system for printing electrodes of a solar cell by automatically positioning according to claim 1, wherein the electrode printing apparatus comprises a blade component, an ink return blade, a screen frame and a screen.

5. The system for printing electrodes of a solar cell by automatically positioning according to claim 1, wherein the visual positioning module comprises a charge coupled device camera.

6. The system for printing electrodes of a solar cell by automatically positioning according to claim 1, further comprising a drying apparatus configured to dry the solar cell after the electrodes have been printed on the solar cell.

7. The system for printing electrodes of a solar cell by automatically positioning according to claim 2, further comprising a drying apparatus configured to dry the solar cell after the electrodes have been printed on the solar cell.

8. The system for printing electrodes of a solar cell by automatically positioning according to claim 3, further comprising a drying apparatus configured to dry the solar cell after the electrodes have been printed on the solar cell.

9. The system for printing electrodes of a solar cell by automatically positioning according to claim 4, further comprising a drying apparatus configured to dry the solar cell after the electrodes have been printed on the solar cell.

10. The system for printing electrodes of a solar cell by automatically positioning according to claim 5, further comprising a drying apparatus configured to dry the solar cell after the electrodes have been printed on the solar cell.

11. The system for printing electrodes of a solar cell by automatically positioning according to claim 6, further comprising a light source arranged on the transparent glass plate.

12. A method for printing electrodes of a solar cell by automatically positioning, comprising:
transmitting a solar cell onto a transparent glass plate;
acquiring position information of the solar cell;
adjusting a position of an electrode printing apparatus according to the position information; and
forming electrodes on the solar cell by screen printing.

13. The method for printing electrodes of a solar cell by automatically positioning according to claim 12, wherein the transmitting a solar cell onto a transparent glass plate comprises:
transmitting the solar cell onto the transparent glass plate by means of a conveying mechanism and absorbing the solar cell onto the transparent glass plate by means of a vacuum chuck.
